(19) United States
(12) Patent Application Publication
(10) Pub. No.: US 2009/0203190 A1
(43) Pub. Date: Aug. 13, 2009

(54) Method of forming a mask stack pattern and method of manufacturing a flash memory device including an active area having rounded corners

(75) Inventors: Young-jin Noh, Suwon-shi (KR); Si-young Choi, Seongnam-si (KR); Bon-young Koo, Suwon-si (KR); Ki-hyun Hwang, Seongnam-si (KR); Chul-sung Kim, Seongnam-si (KR); Sung-kweon Baek, Suwon-si (KR); Jin-hwa Heo, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd

(21) Appl. No.: 12/320,435

(22) Filed: Jan. 26, 2009

(30) Foreign Application Priority Data
Jan. 24, 2008 (KR) 10-2008-0007575

(51) Int. Cl. H01L 21/762; H01L 21/30

(52) U.S. Cl. 438/437; 438/798; 257/E21.546; 257/E21.211

(57) ABSTRACT

A method of forming a mask stack pattern and a method of manufacturing a flash memory device including an active area having rounded corners are provided. The method of manufacture including forming a mask stack pattern defining an active region, the mask stack pattern having a pad oxide layer formed on a semiconductor substrate, a silicon nitride layer formed on the pad oxide layer and a stack oxide layer formed on the silicon nitride layer, oxidizing a surface of the semiconductor substrate exposed by the mask stack pattern and lateral surfaces of the silicon nitride layer such that corners of the active region are rounded, etching the semiconductor substrate having an oxidized surface to form a trench in the semiconductor substrate, forming a device isolation oxide layer in the trench, removing the silicon nitride layer from the semiconductor substrate, and forming a gate electrode in a portion where the silicon nitride layer is removed.

### PRIORITY STATEMENT

This application claims the benefit of priority under 35 U.S.C. §119 from Korean Patent Application No. 10-2008-0007575, filed on Jan. 24, 2008 in the Korean Intellectual Property Office, the disclosure of which is incorporated herein in its entirety by reference.

### BACKGROUND

1. Field

Example embodiments relate to a method of forming a mask pattern and a method of manufacturing a semiconductor device. Other example embodiments relate to a method of forming a mask stack pattern having rounded corners and a method of manufacturing a flash memory device including an active area having rounded corners.

2. Description of the Related Art

If an electric field is concentrated at the corners of an active area of a flash memory device, the reliability of the device may be adversely affected. For example, the concentrated electric field may cause damage to a tunnel oxide layer. In order to reduce (or prevent) a decrease in the reliability of the device and/or damage to the tunnel oxide layer, corners of the active area may be rounded.

In order to round the corners of a cell active area, a bird's beak oxidation (BBOX) method may be used. The BBOX process is used to round corners of an active area using an oxidation process prior to performing a trench etching process for forming a device isolation layer. The name BBOX is derived from the fact that the shape of a silicon oxide formed therein is similar to a bird's beak.

FIGS. 1A and 1B illustrate a process of rounding corners of an active area using the BBOX process.

Referring to FIG. 1A, a BBOX process may be performed on a semiconductor substrate 10 having a mask stack pattern 20 having a pad oxide layer 21, a silicon nitride layer 22, and a stack oxide layers 23 formed thereon. A conventional BBOX method may be performed at a temperature of about 1000° C., in an atmosphere of steam (H₂O), oxygen radical (O₂—) and/or hydroxyl group (OH—). Referring to FIG. 1B, an oxide layer 21′ may be formed on exposed portions of the semiconductor substrate 10 between the mask stack patterns 20 using a BBOX process. The oxide layer 21′ may be thicker than the pad oxide layer 21 below the mask stack patterns 20. The corners of an active area may be rounded due to the difference in the thicknesses of the pad oxide layer 21 and the oxide layer 21′.

As the size of cells decrease, the size of the active area decreases. A punch through effect, in which the active area below the pad oxide layer 21 is oxidized, may occur. Because the corners of the active area may be excessively rounded due to the punch through of the pad oxide layer 21, an effective surface area of the active area may be decrease. The mask stack pattern 20 may be lifted up and bent by the thick oxide layer at the excessively rounded portions.

In order to reduce (or prevent) excessive rounding of the corners of the active area, a target oxidation amount of the BBOX process may be decreased (or reduced). If the target oxidation amount is decreased (or reduced), the oxidation amount of the lateral surfaces of the silicon nitride layer 22 in the mask stack pattern 20 decreases, which may cause the width of a gate electrode to increase during the process of forming a self-arrangement gate electrode and the device isolation layer.

FIGS. 2A and 2B and 3A and 3B illustrate extensions of a critical dimension (CD) of a gate electrode and a profile of an active area according to the lateral oxidation amount of a silicon nitride layer after a conventional BBOX process is performed.

In FIGS. 2A and 3A, after the BBOX process is performed, a semiconductor substrate 10 may be etched to form a trench 15. A device isolation layer 25 may be filled in the trench 15. A silicon nitride layer 22 may be used as a stopper layer to planarize the device isolation layer 25. In FIG. 2A, the lateral oxidation amount of the silicon nitride layer 22 of the BBOX process is the same as a target silicon oxidation amount. In FIG. 3A, the lateral oxidation amount of the silicon nitride layer 22 is less than the target silicon oxidation amount. The width of the silicon nitride layer 22 of FIG. 3A, with less lateral oxidation amount, is larger than the width of the silicon nitride layer 22 of FIG. 2A with greater lateral oxidation amount.

In FIGS. 2B and 3B, the silicon nitride layer 22 and a pad oxide layer 21 are removed. A tunnel oxide layer 31 may be formed. A gate electrode 32 may be formed using polysilicon in portions where the silicon nitride layer 22 has been removed. If the lateral oxidation amount of the silicon nitride layer 22 is the same as the target oxidation amount, the gate electrode 32 having a similar width as the width of the active area of the semiconductor substrate 10 (as illustrated in FIG. 2B) may be obtained. If the lateral oxidation amount of the silicon nitride layer 22 is less than the target oxidation amount, the gate electrode 32 may extend outside of the active area.

The width of the gate electrode 32 may be extended in the following manner. A lateral side of the device isolation oxide layer 25, which is exposed as the silicon nitride layer 22 is removed, may be slowly corroded during a phosphoric strip process for removing the silicon nitride layer 22. A wet etching process may be performed for removing the pad oxide layer 21. A washing process may be performed for forming the tunnel oxide layer 31. As such, the width of the removed portions of the silicon nitride layer 22 may be extended. The width of the gate electrode 32, which is filled in the portions where the silicon nitride layer 22 is removed, may be extended. As similarly shown in FIGS. 3A and 3B, if the lateral oxidation amount of the silicon nitride layer 22 is small, the width of the portions where the silicon nitride layer 22 is removed may increase.

As the width of the gate electrode 32 is extended, the device isolation oxide layer 25 is dented. The corners of the tunnel oxide layer 31 of a gate electrode 130 may become thinner. Coupling between the gate electrodes 32 may increase as the distance between the gate electrodes 32 is reduced, degrading the reliability of the device.

### SUMMARY

Example embodiments relate to a method of forming a mask pattern and a method of manufacturing a semiconductor device. Other example embodiments relate to a method of forming a mask stack pattern having rounded corners and a method of manufacturing a flash memory device including an active area having rounded corners.

Example embodiments provide a bird's beak oxidation (BBOX) process in which the lateral oxidation amount of a silicon nitride layer does not decrease if the target silicon oxidation amount is decreased in order to prevent (or reduce) the likelihood of a punch through effect occurring in a pad oxide layer.

According to example embodiments, there is provided a method of manufacturing a flash memory device, including forming a mask stack pattern having a pad oxide layer formed on a semiconductor substrate, a silicon nitride layer formed on the pad oxide layer, and a stack oxide layer formed on the silicon nitride layer for defining an active region. A surface of the semiconductor substrate that is exposed by the mask stack pattern and lateral surfaces of the silicon nitride layer may be oxidized using a remote plasma oxidation method in an atmosphere including O₂ gas and at least one gas selected from the group consisting of N₂, NO, N₂O and combinations thereof, in order to round corners of the active region. The semiconductor substrate having an oxidized surface may be etched using the mask stack pattern as a mask to form a trench in the semiconductor substrate. A device isolation oxide layer may be formed in the trench. The silicon nitride layer may be removed from the semiconductor substrate on which the device isolation oxide layer is formed. A gate electrode may be formed in a portion where the silicon nitride layer is removed.

Oxidizing the surface of the semiconductor substrate may be performed under a condition in which the oxidation selectivities of the semiconductor substrate and the silicon nitride layer are identical.

Oxidizing the surface of the semiconductor substrate may be performed in a temperature range of about 700° C.-about 950° C., a power range of about 1000 W-about 3000 W and/or a pressure range of about 1 Torr-about 5 Torr.

The device isolation oxide layer may include a high density plasma (HDP) oxide layer or an undoped silicate glass (USG) oxide layer. The stack oxide layer may include a high temperature oxide (HTO) layer, an amorphous carbon layer (ACL) and/or a plasma enhanced SiON (PE-SiON) layer.

Forming the device isolation oxide layer may include forming a sidewall oxide layer on sidewalls of the trench, and forming a liner nitride layer on the sidewall oxide layer.

Removing the silicon nitride layer may include a strip process using phosphoric acid.

The method may include removing the pad oxide layer after removing the silicon nitride layer, and performing a hole washing process after removing the pad oxide layer and forming a tunnel oxide layer on the semiconductor substrate.

### BRIEF DESCRIPTION OF THE DRAWINGS

Example embodiments will be more clearly understood from the following detailed description taken in conjunction with the accompanying drawings. FIGS. 1A-1B, 2A-2B, 3A-3B, 4A-4F, 5 and 6 represent non-limiting, example embodiments as described herein.

FIGS. 1A and 1B are diagrams illustrating a process of rounding corners of an active area using a bird's beak oxidation (BBOX) process according to the conventional art;

FIGS. 2A and 2B are diagrams illustrating an extension of a critical dimension (CD) of a gate electrode and a profile of an active area having the lateral oxidation amount of a silicon nitride layer according to the conventional art;

FIGS. 3A and 3B are diagrams illustrating an extension of a CD of a gate electrode and a profile of an active area having the lateral oxidation amount of a silicon nitride layer according to the conventional art;

FIGS. 4A through 4F are diagrams illustrating cross-sectional views of a method of manufacturing a flash memory device by performing the BBOX process according to example embodiments;

FIG. 5 is a graph illustrating the oxidation amount of silicon versus silicon nitride in the BBOX process according to example embodiments and the conventional art for a variety of process conditions; and

FIG. 6 is a scanning electron microscope (SEM) photograph showing a cross-section of a profile of an active area formed by performing the BBOX process according to example embodiments.

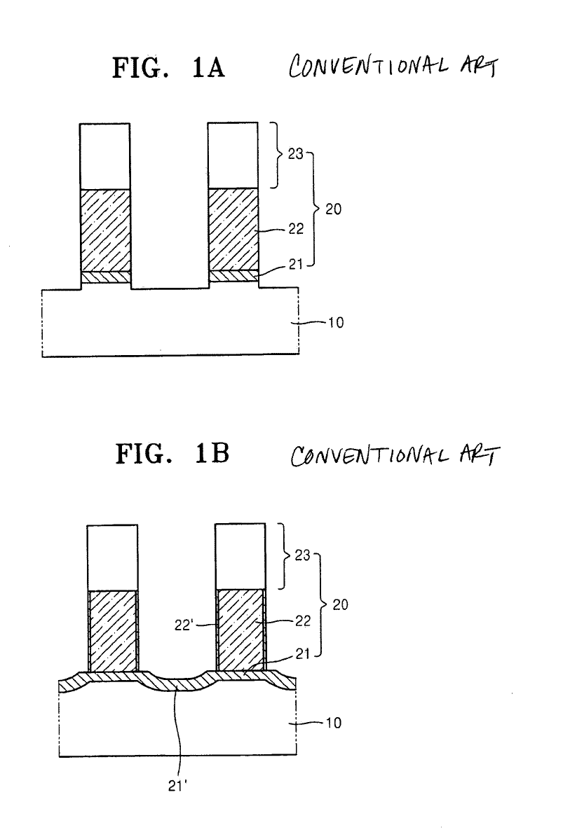

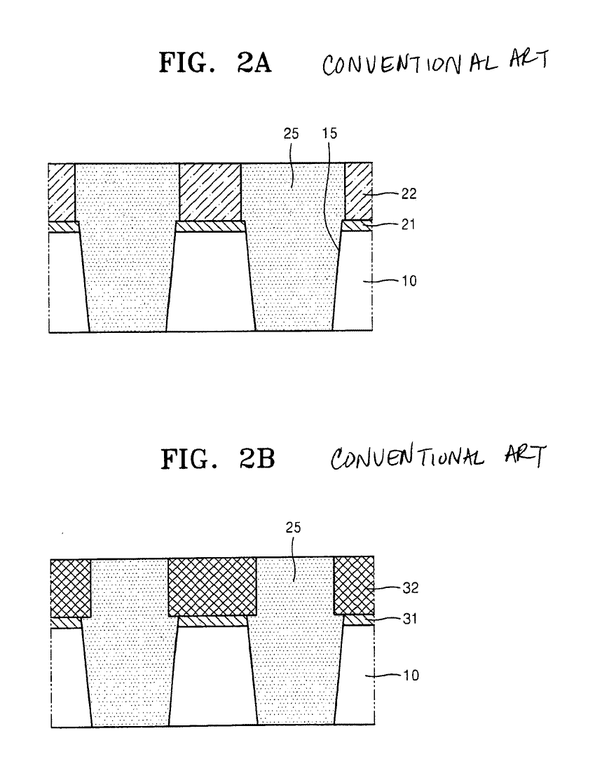

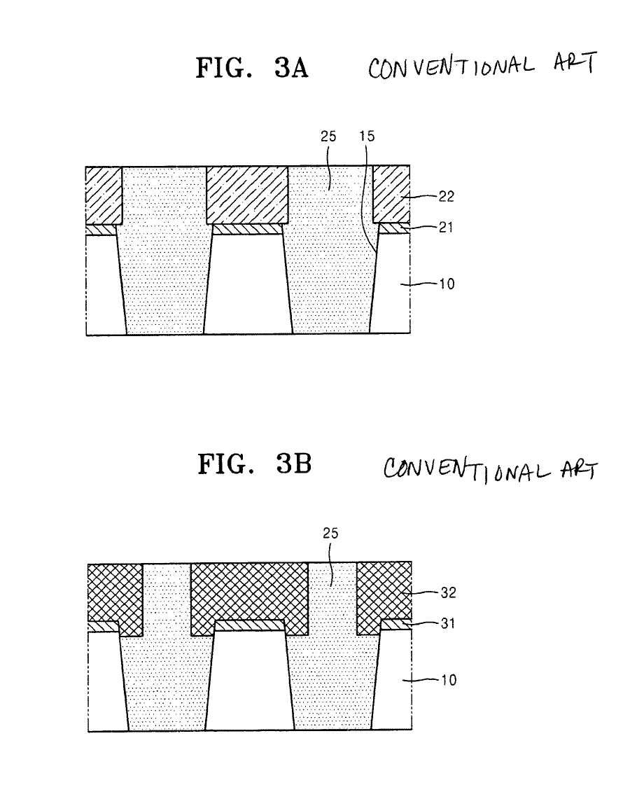

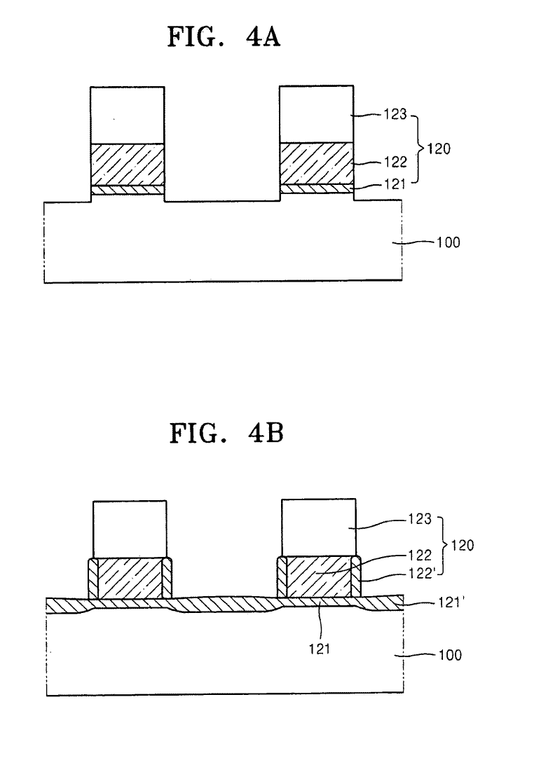

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to a method of forming a mask pattern and a method of manufacturing a semiconductor device. Other example embodiments relate to a method of forming a mask stack pattern having rounded corners and a method of manufacturing a flash memory device including an active area having rounded corners.

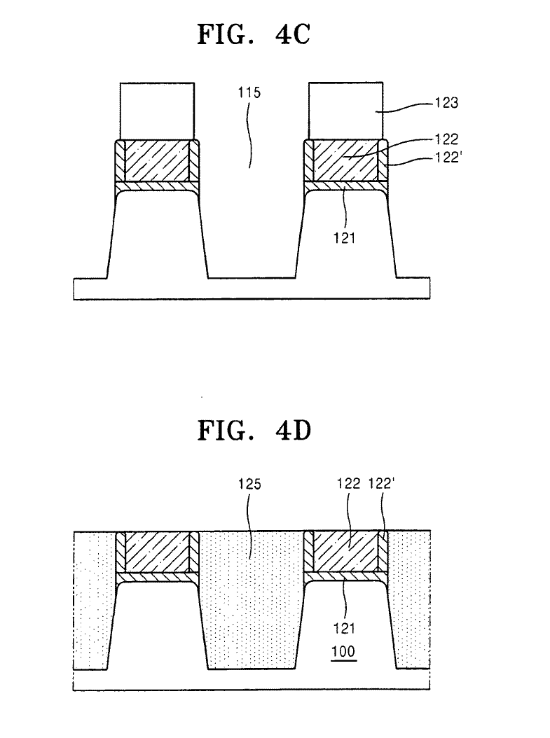

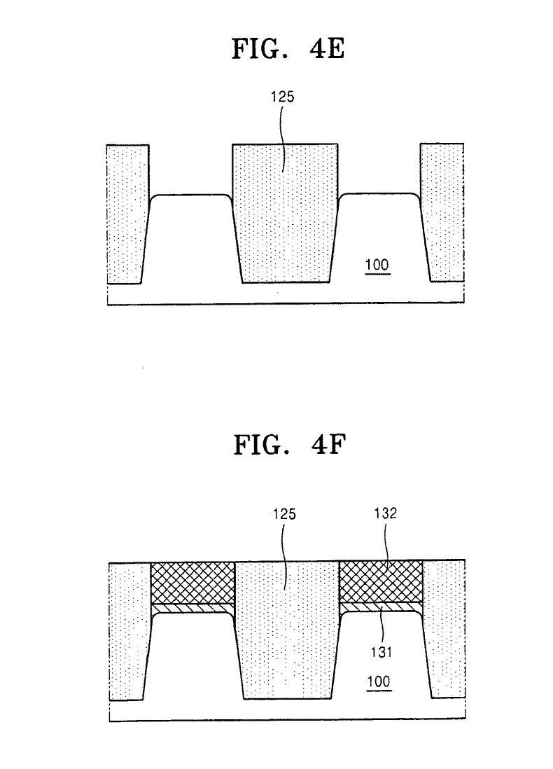

FIGS. 4A through 4F are cross-sectional views illustrating a method of manufacturing a flash memory device by performing a bird's beak oxidation (BBOX) process according to example embodiments.

Referring to FIG. 4A, a mask stack pattern 120 including a pad oxide layer 121, a silicon nitride layer 122 and a stack oxide layer 123 may be formed on a semiconductor substrate 100. The mask stack pattern 120 defines an active area. The stack oxide layer 123 may be formed by sequentially stacking a high temperature oxide (HTO) layer, an amorphous carbon layer (ACL) and a plasma-enhanced SiON (PE-SiON) layer.

Referring to FIG. 4B, the semiconductor substrate 100, on which the mask stack pattern 120 is formed, may be oxidized to form an oxide layer 121′ on a surface of the semiconductor substrate 100 and an oxide layer 122′ on lateral surfaces of the silicon nitride layer 122. The BBOX process may be performed such that the oxidation selectivity of the semiconductor substrate 100 and the silicon nitride layer 122 is about 1:1. The BBOX process may be performed using a remote plasma oxidation method using at least one of a N₂ gas, a NO gas, a N₂O gas which contains nitrogen (N) and O₂ gas, or combinations thereof. The thickness of the oxide layer 121′ of the semiconductor substrate 100 may be greater than the thickness of the pad oxide layer 121. Portions where the pad oxide layer 121 and the oxide layer 121′ of the semiconductor substrate contact may be curved like a bird's beak. By using the curved form of the oxide layer 121′, corners of the active area below the mask stack pattern 120 may be rounded.

Referring to FIG. 4C, a trench 115 may be formed by using the mask stack pattern 120 as a mask and etching the semiconductor substrate 100. After the trench 115 is formed, the corners of the active area below the mask stack pattern 120 may be rounded from the oxide layer 121′.

Referring to FIG. 4D, a device isolation oxide layer 125 may be formed in the trench 115. The device isolation oxide layer 125 may be formed by depositing a high density plasma (HDP) oxide layer (not shown) or an undoped silicate glass (USG) oxide layer (not shown) so as to fill the trench 115. The HDP oxide layer or the USG oxide layer may be chemically mechanically polished (CMP) using the mask stack pattern 120 as a mask. The stack oxide layer 123 may be removed as CMP is performed on the device isolation oxide layer 125. The silicon nitride layer 122 functions as a stopper layer for the CMP process. The process of forming the device isolation oxide layer 125 may include forming a sidewall oxide layer (not shown) on sidewalls of the trench 115 and forming a liner nitride layer (not shown) prior to forming the device isolation oxide layer 125 in order to alleviate stress applied to inner walls of the trench 115.

Referring to FIG. 4E, the silicon nitride layer 122 and the pad oxide layer 121 may be removed. The silicon nitride layer 122 may be removed using a phosphoric acid strip process. The pad oxide layer 121 may be removed using a wet etching process.

Referring to FIG. 4F, a tunnel oxide layer 131 and a gate electrode 132 may be formed in portions where the silicon nitride layer 122 and the pad oxide layer 121 are removed. The tunnel oxide layer 131 may be formed by thermal oxidation of the semiconductor substrate 100 or by depositing a dielectric layer having a higher dielectric constant. The gate electrode 132 may be formed of a polycrystalline silicon or a metal.

In the flash memory device manufactured as described above, the difference between the critical dimension (CD) of the silicon nitride layer 122 and the CD of the gate electrode 132 (that is formed after the silicon nitride layer 122 is removed) may be minimal. As, deterioration of the device reliability, due to the device isolation oxide layer 125 being dented because of the extension of CD of the gate electrode 132 or due to coupling between the gate electrodes 132, may be reduced (or prevented). The BBOX process according to example embodiments may be applied not only to flash memory devices but also to other semiconductor devices that require rounding of an active area.

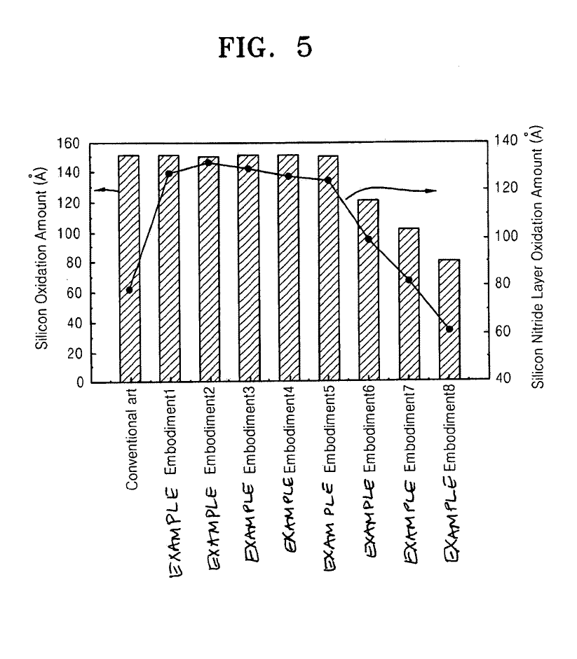

FIG. 5 is a graph of the oxidation amount of silicon versus a silicon nitride layer in the BBOX process according to example embodiments and the conventional art. The oxidation amount in the BBOX process according to example embodiments is measured according to temperature and power. Example embodiments 1, 2 and 3 were performed in a temperature range of 750° C.-850° C., or about 750° C.-850° C. (e.g., about 750° C. and/or about 850° C.). Example embodiments 1, 4 and 5 were performed in the power range of 1000 W-3000 W, or about 1000 W-3000 W (e.g., about 1000 W and/or about 3000 W). A target oxide layer of example embodiments 1 through 5 is 150 Å. Example embodiments 6, 7 and 8 have an oxidation target of 80 Å-120 Å, or about 80 Å-120 Å (e.g., about 80 Å and/or about 120 Å). In example embodiments 1-8, O₂ and N₂ gases are used. In the conventional art, an atmosphere of steam (H₂O), oxygen radical (O₂—) and hydroxyl group (OH—) was used.

In FIG. 5, the silicon oxidation amount denoted by bar graphs show the thicknesses of the silicon oxide layer after the BBOX process is applied to a bare wafer. In FIG. 5, the oxidation amount of the silicon nitride layer denoted by a line is the difference between the thickness of the silicon nitride after being deposited, and the thickness of the silicon nitride layer remaining after removing SiON formed in the BBOX process. The measurements of example embodiments of FIG. 5 are obtained by performing a remote plasma oxidation method using O₂ gas and N₂ gas.

In FIG. 5, in example embodiments 1-5 having a target of forming a silicon oxide layer of 150 Å, the ratios of the oxidation amounts of silicon and silicon nitride layer are approximately 1:1. Example embodiments 1-5 do not have a substantially large variance with respect to temperature and power. The ratios according to example embodiments increased by a factor of two over that of the conventional oxidation process shown in FIG. 5.

Based on the above result, if a silicon oxide layer of 100 Å is formed, the amount of oxidation of the silicon nitride layer is about 80 Å, which is the same as the oxidation amount of the silicon nitride layer if a silicon oxide layer of 150 Å is formed in a conventional BBOX process. According to the BBOX process applied to example embodiments, the lateral oxidation amount of the silicon nitride layer may remain the same while reducing the target oxidation amount of the silicon. The oxidation ratio of silicon versus a silicon nitride layer may be substantially large during the BBOX process according to example embodiments due to the substantially small activation energy of the remote plasma oxidation process using O₂ and N₂ gases. As such, the oxidation speed not only for silicon, but also for the silicon nitride layer, may be substantially high.

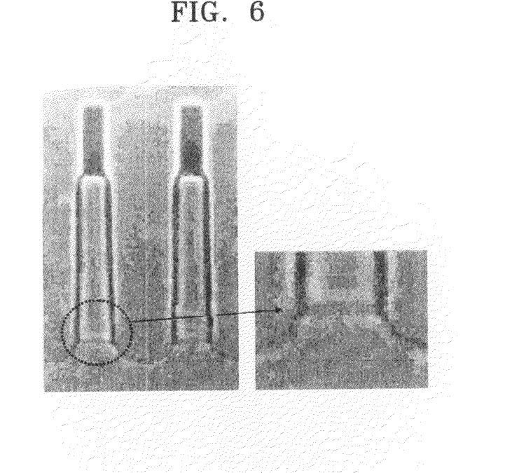

FIG. 6 is a scanning electron microscope (SEM) photograph showing a cross-section of a profile of an active area formed by performing the BBOX process according to example embodiments. The CD of a mask stack pattern was 0.26 Å, and the target silicon oxidation amount was 100 Å. The lateral oxidation amount of the silicon nitride layer was maintained the same as if the target silicon oxidation amount was 150 Å. As the silicon oxidation amount is reduced to 100 Å, a punch through effect in the pad oxide layer and excessive rounding of corners of the active area does not occur, ensuring a more effective surface area of the active area. The mask stack pattern including the silicon nitride layer is not bent at the corners of the active area. Because the lateral oxidation amount of the silicon nitride layer is not reduced, the extension of the CD of the gate electrode may be prevented (or reduced). Also, denting of the device isolation oxide layer may be prevented. As such, an edge of the tunnel oxide layer may be prevented from becoming thinner, increasing reliability of the device.

According to example embodiments, the oxidation process of a semiconductor substrate for rounding corners of an active area is performed such that the difference between oxidation selectivities of silicon and a silicon nitride layer may be minimal. As such, the lateral oxidation amount of the silicon nitride layer, which constitutes a mask pattern of the active area and is a frame for a self-arrangement gate electrode, may not decrease even if the target silicon oxidation amount of the semiconductor substrate decreases in order to prevent punch through in a pad oxide layer. If the lateral oxidation amount of the silicon nitride layer is not decreased, deterioration of the device reliability, due to denting of a device isolation oxide layer because of the loss of the device isolation oxide layer during a wet etching process and a washing process and/or coupling between gate electrodes, may be prevented.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of forming a mask stack pattern, comprising:
forming a pad oxide layer on a semiconductor substrate, a silicon nitride layer on the pad oxide layer and a stack oxide layer on the silicon nitride layer, the pad oxide layer, the silicon nitride layer and the stack oxide layer collectively defining an active region; and
oxidizing a surface of the semiconductor substrate that is exposed by the active region and lateral surfaces of the silicon nitride layer using a remote plasma oxidation method such that corners of the active region are rounded, the remote plasma oxidation method being performed in an atmosphere including O₂ gas and at least one gas selected from the group consisting of N₂, NO, N₂O gases and combinations thereof.

2. The method of claim 1, wherein oxidizing the surface of the semiconductor substrate is performed under a condition in which oxidation selectivities of the semiconductor substrate and the silicon nitride layer are identical.

3. The method of claim 1, wherein oxidizing the surface of the semiconductor substrate is performed in a temperature range of about 700° C.-950° C.

4. The method of claim 1, wherein oxidizing the surface of the semiconductor substrate is performed in a power range of about 1000 W-3000 W.

5. The method of claim 1, wherein oxidizing the surface of the semiconductor substrate is performed in a pressure range of about 1 Torr-5 Torr.

6. The method of claim 1, wherein the stack oxide layer includes a high temperature oxide (HTO) layer, an amorphous carbon layer (ACL) and a plasma enhanced SiON (PE-SiON) layer.

7. A method of manufacturing a flash memory device, comprising:
forming the mask stack pattern according to claim 1,
etching the semiconductor substrate having an oxidized surface using the mask stack pattern as a mask to form a trench in the semiconductor substrate;
forming a device isolation oxide layer in the trench;
removing the silicon nitride layer from the semiconductor substrate on which the device isolation oxide layer is formed; and
forming a gate electrode in a portion where the silicon nitride layer is removed.

8. The method of claim 7, wherein oxidizing the surface of the semiconductor substrate is performed under a condition in which oxidation selectivities of the semiconductor substrate and the silicon nitride layer are identical.

9. The method of claim 7, wherein oxidizing the surface of the semiconductor substrate is performed in a temperature range of about 700° C.-950° C.

10. The method of claim 7, wherein oxidizing the surface of the semiconductor substrate is performed in a power range of about 1000 W-3000 W.

11. The method of claim 7, wherein oxidizing the surface of the semiconductor substrate is performed in a pressure range of about 1 Torr-5 Torr.

12. The method of claim 7, wherein the device isolation oxide layer includes a high density plasma (HDP) oxide layer or an undoped silicate glass (USG) oxide layer.

13. The method of claim 7, wherein the stack oxide layer includes a high temperature oxide (HTO) layer, an amorphous carbon layer (ACL) and a plasma enhanced SiON (PE-SiON) layer.

14. The method of claim 7, wherein forming the device isolation oxide layer includes forming a sidewall oxide layer on sidewalls of the trench; and forming a liner nitride layer on the sidewall oxide layer.

15. The method of claim 7, wherein removing the silicon nitride layer includes performing a strip process using phosphoric acid.

16. The method of claim 7, further comprising:
removing the pad oxide layer after removing the silicon nitride layer;
performing a hole washing process after removing the pad oxide layer; and
forming a tunnel oxide layer on the semiconductor substrate.
